(19) United States
(12) Patent Application Publication
(10) Pub. No.: US 2017/0294454 A1
(43) Pub. Date: Oct. 12, 2017

(54) ARRAY SUBSTRATE AND FABRICATING METHOD THEREOF, DISPLAY PANEL, AND DISPLAY APPARATUS

(71) Applicant: BOE TECHNOLOGY GROUP CO., LTD, Beijing (CN)

(72) Inventors: Ce NING, Beijing (CN); Wei YANG, Beijing (CN)

(21) Appl. No.: 15/324,909

(22) PCT Filed: Oct. 29, 2015
(86) PCT No.: PCT/CN2015/093193

§ 371 Date: Jan. 9, 2017

(51) Int. Cl. H01L 27/12; G02F 1/1368

(52) U.S. Cl. CPC H01L 27/1225; H01L 27/127; G02F 1/1368

(57) ABSTRACT

The present disclosure provides an array substrate and fabricating method thereof, a display panel, and a display apparatus. A first active layer and common electrodes are formed on the substrate. A first gate insulating layer is formed on the first active layer. A gate electrode is formed on the first gate insulating layer. A second gate insulating layer is formed on he common electrodes and the gate electrode. Via-holes are formed in the second gate insulating layer to expose surface portions of the common electrodes. Source/drain electrodes are formed and electrically connected to the coma on electrodes through the via-holes. A second active layer and pixel electrodes are formed on the second gate insulating layer.

### FIELD OF THE DISCLOSURE

The present disclosure generally relates to the field of display technologies and, more particularly, relates to an array substrate and a fabricating method thereof, a display panel, and a display apparatus.

### BACKGROUND

Thin film transistor liquid crystal display (TFT-LCD) has the advantages of compact size, low power consumption, and radiation free. The ADS (advanced super dimension switch) technology is capable of improving the image quality of TFT-LCD products.

Amorphous silicon (a-Si) techniques are often used for forming large-size LCD devices at low temperatures. However, the bandgap of a-Si material is only about 1.7V, opaque to visible light but photosensitive in the visible range. An opaque metal mask or black matrix may then be used to block out the light. This increases complexity and cost for fabricating the LCD devices with reduced reliability and aperture ratio. In many cases, to obtain sufficient brightness, light intensity has to be increased, which in turn increases power consumption of the display device.

Further, it is difficult to increase mobility of hydrogenated amorphous silicon semiconductor to exceed 1 cm²·V⁻¹·s⁻¹. Existing hydrogenated amorphous silicon TFT faces challenges from demanding for LCD TVs with ever-increasing sizes and for high-performance driving circuit.

The disclosed array substrates, fabricating methods, and display devices are directed to at least partially alleviate one or more problems set forth above and to solve other problems in the art.

### BRIEF SUMMARY OF THE DISCLOSURE

One aspect or embodiment of the present disclosure provides a method for fabricating an array substrate. A first active layer and common electrodes are formed on the substrate. A first gate insulating layer is formed on the first active layer. A gate electrode is formed on the first gate insulating layer. A second gate insulating layer is formed on the common electrodes and the gate electrode. Via-holes are formed in the second gate insulating layer to expose surface portions of the common electrodes. Source/drain electrodes are for tied and electrically connected with the common electrodes through the via-holes. A second active layer and pixel electrodes are formed on the second gate insulating layer.

Optionally, the step of forming a first active layer and common electrodes on the substrate includes forming a first oxide layer between the substrate and the first gate insulating layer. The first oxide layer has a first portion under the first gate insulating layer used as the first active layer, and has a second portion on the substrate being converted into a conductive layer used as the common electrodes.

Optionally, the second portion of the first oxide layer is convened into the conductive layer by a plasma.

Optionally, the second portion of the first oxide layer is converted into the conductive layer by an ion implantation process.

Optionally, a first patterned photoresist layer is used as an etch mask, to form the first active layer, the common electrodes, the first gate insulating layer, and the gate electrode.

Optionally, a first insulating layer is formed on the first oxide layer, and a metal layer is formed on the first insulating layer. The first patterned photoresist layer is formed on the metal layer and used as the etch mask.

Optionally, a through-hole is formed in the metal layer, the first insulating layer, and the first oxide layer to expose the substrate. A first portion of the first patterned photoresist layer containing, the through-hole is removed to leave a second portion of the first patterned photoresist layer remain on the metal layer. The second portion of the first patterned photoresist layer is used as an etch mask to remove portions of the metal layer and the first insulating layer, to provide the first gate insulating layer and the gate electrode.

Optionally, the step of using the second portion of the first patterned photoresist layer as an etch mask to remove portions of the first insulating layer includes a dry etching process using plasma.

Optionally, the dry etching process is controlled to use the plasma to simultaneously treat the first oxide layer to convert the first oxide layer that is not under the first gate insulating layer into the conductive layer.

Optionally, the step of forming, a second active layer and pixel electrodes includes: forming a second oxide layer on the second gate insulating layer and on the source/drain electrodes, and forming a protection layer on the second oxide layer.

Optionally, after forming the source/drain electrodes and before forming the second active layer, a second patterned photoresist layer is thrilled on the protection layer. The second patterned photoresist layer is used on the protection layer as an etch mask to form the second active layer and the pixel electrodes an the second gate insulating layer.

Another aspect or embodiment of the present disclosure provides an array substrate. The array substrate includes a first layer including a first active layer and common electrodes on the substrate, a first gate insulating layer on the first active layer; a gate electrode on the first gate insulating layer; a second gate insulating layer on the common electrodes and the gate electrode; source/drain electrodes in the second gate insulating layer and connecting to the common electrodes; a second active layer on the second gate insulating layer, above the gate electrode, and between the source/drain electrodes; and pixel electrodes on the second gate insulating layer.

Optionally, the first layer is a first oxide layer between the substrate and the first gate insulating layer. The first oxide layer has a first portion under the first gate insulating layer defined as the first active layer, and has a second portion being converted into a conductive layer defined as the common electrodes.

Optionally, the second portion of the first oxide layer is converted into the conductive layer by a plasma. Optionally, the second portion of the first oxide layer is converted into the conductive layer by an ion implantation process.

Optionally, a second oxide layer is on the second gate insulating layer and on the source/drain electrodes. The second oxide layer has a first portion over the first gate insulating layer defined as the second active layer, and has a second portion being converted into a conductive layer defined as the pixel electrodes.

Optionally, the second portion of the second oxide layer is converted into the conductive layer by a plasma or an ion implantation.

Optionally, each of the first and second active layers has a thickness ranging from about 30 nm to, about 50 nm.

Optionally, each of the first and second active layers is made of indium gallium zinc oxide (IGZO), indium zinc oxide (IZO), indium-tin-zinc-oxide (ITZO), zinc oxide (ZnO), or a combination thereof.

Another aspect or embodiment of the present disclosure provides a displays-panel includes the disclosed array substrate.

Another aspect or embodiment of the present disclosure provides a display apparatus includes the disclosed display panel.

Other aspects or embodiments of the present disclosure can be understood by those skilled in the art in fight of the description, the claims, and the drawings of the present disclosure.

### BRIEF DESCRIPTION OF THE DRAWINGS

The following drawings are merely examples for illustrative purposes according to various disclosed embodiments and, are not intended to limit the scope of the present disclosure.

FIGS. 1-8 illustrate cross sectional structures of an exemplary array substrate at certain stages during its formation according to various embodiments of the present disclosure.

### DETAILED DESCRIPTION

The objectives, features and advantages of the present disclosure may be more fully understood by persons of ordinary skill in the art with reference to the exemplary embodiments which are described in detail below and are illustrated in the accompanying drawings. Wherever possible, the same reference numbers will be used throughout the drawings to refer to the same or like parts.

The present disclosure provides an array substrate and fabricating method thereof, and a display panel including the array substrate, and a display apparatus including the display panel.

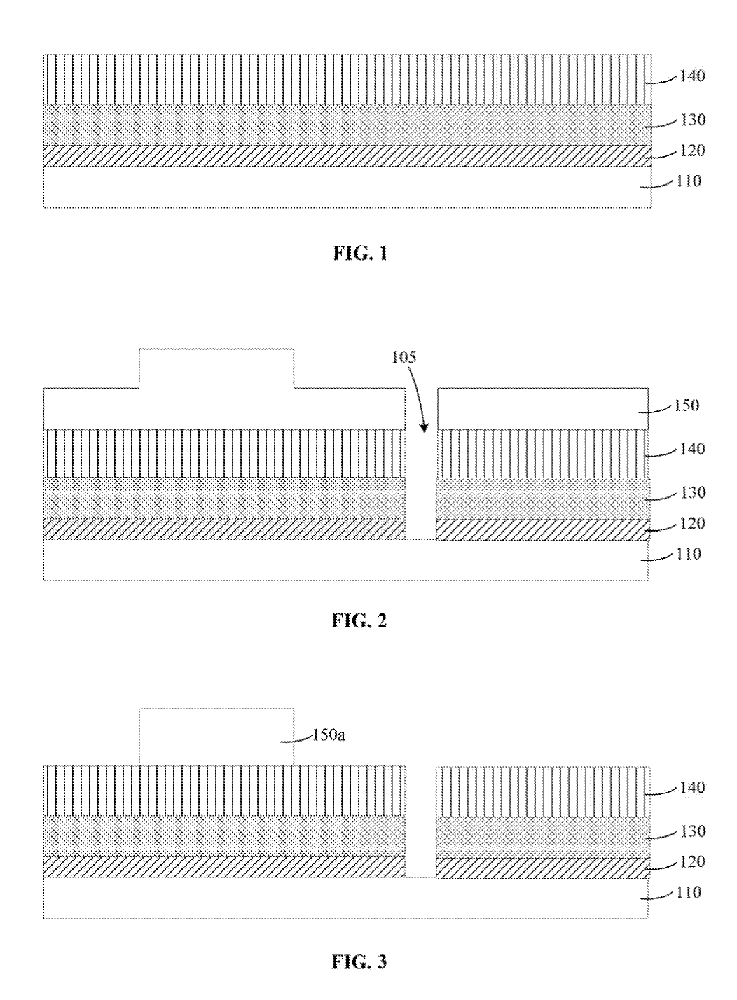

FIGS. 1-8 illustrate cross sectional structures of an exemplary array substrate at certain stages during its formation according to various embodiments of the present disclosure.

in FIG. 1, a substrate 110 is provided. A first oxide layer 120, a first insulating layer 130, and a metal layer 140 are sequentially formed on the substrate 110.

The substrate 110 may be an optically transparent substrate. For example, the substrate 110 may be made of glass quartz, plastic. The substrate 110 may be, for example a flexible substrate, made of a polymer. Of course, other suitable substrates may be used for the substrate 110.

The first oxide layer 120 may be formed on the substrate 110. The first oxide layer 120 may be formed by, for example, a magnetron sputtering process. The first oxide layer 120 may have a thickness ranging from about 30 nm to about 50 nm. The first oxide layer 120 may be made of indium gallium zinc oxide (IGZO), indium zinc oxide (IZO), indium-tin-zinc-oxide (ITZO), zinc oxide (ZnO) etc. The first oxide layer 120 may subsequently be processed to form a first active layer, e.g., first active layer 120a in FIGS. 4-8, and common electrodes, e.g., common electrodes 125 in FIGS. 4-8. In one embodiment, the first oxide layer 120 may be formed by a metal oxide semiconductor.

The first insulating layer 130 may be formed on the first oxide layer 120. The first insulating layer 130 may be used to form a first gate insulating layer subsequently.

The first insulating layer 130 may be made of an insulating material such as, for example, silicon nitride (SiNₓ), silicon oxide (SiOₓ), silicon oxynitride (SiOₓN_{y}), aluminum oxide (AlOₓ), yttrium oxide (Y₂O₃), hafnium oxide (HFOx), zirconium oxide (ZrOₓ), aluminum nitride (AlN), aluminum oxynitride (Al₂NO), titanium oxide (TiOₓ), barium titanate (BaTiO₃), lead titanate (PbTiO₃), or a combination thereof.

In one embodiment, the first insulating, layer 130 may be formed by a plasma-enhanced chemical vapor deposition (PECVD) process. The first insulating layer 130 may have a thickness ranging from about 300 nm to about 400 nm.

The metal layer 140 may be formed by, for example, a magnetron sputtering process. The metal layer 140 may have a thickness ranging from about 200 nm to about 300 nm. The metal layer 140 may include, one or more layers with each layer formed by one or more metal material. The metal material may include aluminum (Al), copper (Cu), molybdenum (Mo), titanium (Ti), nickel (Ni), tungsten (W), gold (Au), palladium (Pd), platinum (Pt), chromium (Cr), neodymium (Nd), zinc (Zn), cobalt (Co), manganese (Mn), and any mixtures or alloys thereof.

In FIG. 2, a first patterned photoresist layer 150 may be fanned over the metal layer 140, e.g., using a standard photolithographic process. The first patterned photoresist layer 150 may have an opening there-through to expose the underlying metal layer 140. The first patter ed photoresist layer 150 may then be used as an etch mask to etch the metal layer 140, the first insulating layer 130, and the first oxide layer 120 to form a through-hole 105 in a first etching process, until a surface portion of the substrate 110 is exposed.

The first etching process for forming the through-hole 105 may include a wet etching, a dry etching, or any combinations thereof. In one embodiment, the first etching process may include a wet etching to etch the metal layer 140, a dry etching to etch the first insulating layer 130, and another wet etching to etch the first oxide layer 120. In another embodiment, the first etching process may include one or more dry etching processes to etch the metal layer 40, the first insulating layer 130, and the first oxide layer 120, either together or separately. Still in another embodiment, the first etching process may include one or more wet etching processes to etch the metal layer 140, the first insulating layer 130, and the first oxide layer 120, either together or separately.

As shown in FIG. 2, the first patterned photoresist layer 150 may have a first portion, corresponding to a subsequently-formed active layer/gate electrode, with a thickness greater than a second portion of the first patterned photoresist layer 150. The second portion of the first patterned photoresist layer 150 contains the through-hole 105.

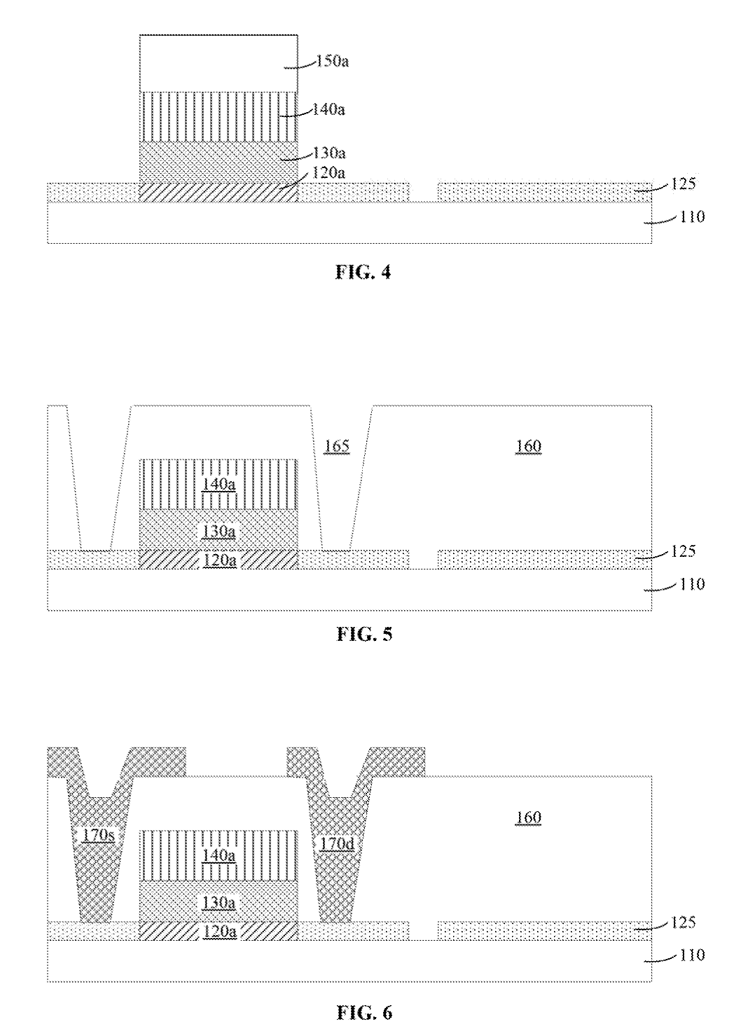

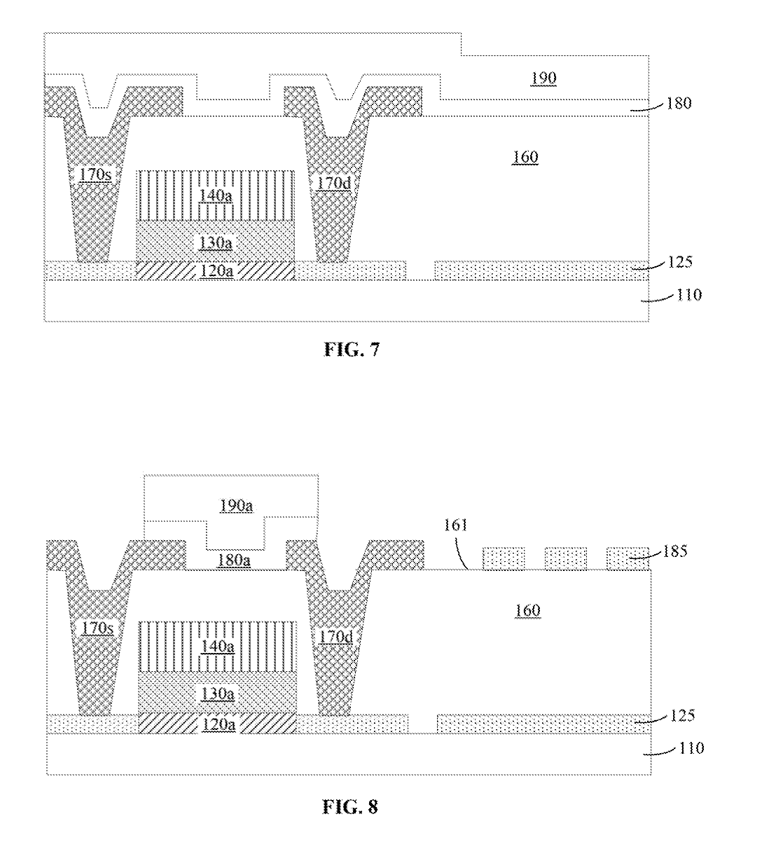

In FIG. 3, the second portion of the first patterned photoresist layer 150 may be removed from the metal layer 140 to leave a remaining photoresist layer 150a. For example, the second portion of the first patterned photoresist layer 150 may be removed by an ashing process.

In FIG. 4, after the first etching process for forming the through-hole 105 through the metal layer 140, the first insulating layer 130, and the first oxide layer 120, a second etching process may be performed to further etch the metal layer and the first insulating layer using the remaining photoresist layer 150a as an etch mask.

After the second etching process, a gate electrode 140a and a first gate insulating layer 130a may remain under the remaining photoresist layer 150a. A portion of the first oxide layer 120 under the remaining photoresist layer 150a may be used as a first active layer 120a on the substrate 110.

In one embodiment, the first gate insulating layer 130a may be formed by a dry etching involved in at least one of the first and second etching processes, as disclosed in FIG. 2 and FIG. 4. The dry etching of the first gate insulating layer 130 may use plasma, for example, including O₂ or O₂ and fluorine (F).

During dry etching of the insulating layer 130 for forming the first gate insulating layer 130a, the exposed first oxide layer 120 that is not under the remaining photoresist layer 150a may be simultaneously treated by the plasma to turn the exposed first oxide layer into a conductive layer, for example, a transparent conductive layer, which may be used as common electrodes 125.

In other embodiments, the first oxide layer 120 that is, not under the remaining photoresist layer 150a may be doped by an ion implantation process to convert the first oxide layer into a conductive layer, for example, a transparent conductive layer, which may be used as the common electrodes 125.

In various embodiments, while the common electrodes 125 are formed, common lines (not shown) may also be formed simultaneously.

As such, by using the first patterned photoresist layer 150, the gate electrode 140a, the first gate insulating layer 130a, the first active layer 120a, and the common electrodes 125 may be formed.

In FIG. 5, after the remaining photoresist layer 150a in FIG. 4 is removed, a second gate insulating layer 160 is formed on the common electrodes 125, the exposed portion of the substrate 110, and the gate electrode 140a. In addition, via-holes 165 may be formed through the second gate insulating layer 160 and on surface portions of the common electrodes 125.

For example, the via-holes 165 may be formed by a standard photolithographic process, for example, using a second patterned photoresist layer (not illustrated) formed on a second gate insulating layer as an etch mask.

In FIG. 6, a source electrode 170s and a drain electrode 170d may be formed in the via-holes 165 to connect to the common electrodes 125, respectively. The source electrode 170s and the drain electrode 170d may also have portions formed on surface of the second gate insulating layer 160.

In various embodiments, the source electrode 170s and the drain electrode 170d May be formed by another standard photolithographic process. For example, an electrode material may be deposited in the via-holes 165 and on the entire surface of the second gate insulating layer 160. A third patterned photoresist layer (not illustrated) may be formed on the electrode material, and may be used as an etch mask to etch the electrode material to expose the second gate insulating layer 160 and to form the source electrode 170s and the drain electrode 170d, as shown in FIG. 6. In other cases, data lines may be formed simultaneously along with the source/drain electrodes 170s/d.

In FIG. 7, a second oxide layer 180 may be formed on the source electrode 170s and the drain electrode 170d, and on the exposed surface of the second gate insulating: layer 160. A protection layer 190 may be formed on the second oxide layer 180.

In various embodiments, the second oxide layer 180 may be the same as or similar to the first oxide layer 120 in FIG. 1.

The protection layer 190 may be a passivation layer formed by insulating material (s). For example, the protection layer 190 may be made of silicon nitride (SiNₓ), silicon oxide (SiOₓ), silicon oxynitride (SiOₓN_{y}), etc. The protection layer 190 may be formed by a PECVD process.

In FIG. 8, a second active layer 180a, a patterned protection layer 190a, and pixel electrodes 185 may be formed by processing the second oxide layer 180 and the protection layer 190 in FIG. 7. This processing may be similar to the processes shown in FIGS. 1-4, where the first oxide layer 120 and the first insulating layer 130 are processed to form the first active layer 120a, the first gate insulating layer 130a, and the common electrodes 125.

For example, a fourth patterned photoresist layer (not illustrated) may be formed on the protection layer 190 in FIG. 7. The fourth patterned photoresist layer may have openings there-through to expose underlying protection layer 190. The fourth patterned photoresist layer may then be used as an etch mask to etch the second oxide layer 180 and the protection layer 190 to form through-holes in a third etching process, until surface portions 161 of the second gate insulating layer 160 are exposed, leaving a plurality of second oxide layer portions thereon. The third etching process may be the same or similar to the first etching process for forming the through-hole 105 as illustrated in FIG. 2.

Similarly to the first patterned photoresist layer 150, the fourth patterned photoresist layer may have a first portion, corresponding to a subsequently-formed second active layer 180a, with a thickness greater than other portions of the fourth patterned photoresist layer.

The other portions of the fourth patterned photoresist layer may be removed to leave a fourth remaining photoresist layer used as an etch mask to further etch the protection layer 190 and the second oxide layer 180 by a fourth etching process. In various embodiments, the fourth etching process may be the same or similar to the second etching process illustrated in FIG. 4.

The fourth remaining, photoresist layer on the patterned protection layer 190a and the second active layer 180a may then be removed, with the plurality of second oxide layer portions on the second gate insulating layer 160 that is not over the gate electrode 140a.

In one embodiment, the protection layer 190 may be patterned by a dry etching involved in at least one of the third insulating layer and the fourth etching process to form the patterned protection layer 190a. The dry etching of the protection layer 190 may use plasma, for example, including, O₂ or O₂ and fluorine (F).

During dry etching of the protection layer 190 for forming the patterned protection layer 190a, the plurality of second oxide layer portions on the second gate insulating layer 160 that is not over the gate electrode 140a may be simultaneously treated by the plasma to convert the exposed second oxide layer into a transparent conductive layer. The transparent conductive layer may be used as pixel electrodes 185 as shown in FIG. 8.

In other embodiments, the plurality of second oxide layer portions on the second gate insulating layer 160 that is not over the gate electrode 140a may be treated by an ion implantation process to convert the exposed second oxide Layer into a conductive layer to form the pixel electrodes 185.

As such, by using the fourth patterned photoresist layer, the second active layer 180a, the patterned protection layer 190a, and the pixel electrodes 185 may be thrilled as shown in FIG. 8.

In this manner, the formed array substrate may thus have a dual-active layer structure having the first active layer 120a and the second active layer 180a. In various embodiments the disclosed array substrate may be formed by four patterning processes, each patterning process uses a patterned photoresist layer as an etch mask for the corresponding patterning process.

For example, in a first patterning process, a first oxide layer such as a metal oxide layer may be deposited on a substrate and a metal layer may be deposited on the first oxide layer. By using the first patterning process, the gate electrode, the first gate insulating layer, the first active layer, common electrodes, and common electrode lines may be formed. In a second patterning process, a second gate insulating layer, is deposited and via-holes are formed in the second gate insulating layer using a second patterning process.

In a third patterning process, source/drain electrode material is deposited and the third patterning process is used to form source/drain electrodes and data lines. In a fourth patterning process, a second oxide layer and a protective layer may be formed, and by using the fourth patterning process, a second active layer, pixel electrodes, and a patterned protective layer, may be formed.

Thus, entire process for forming the disclosed array substrate may only use four patterning processes to form the ADS (advanced super dimension switch) structure. The dual active layer structure may greatly improve on-state current of the resultant display device, and, reduce the pixel charging time. This benefits the resultant display device with large size, with high pixels-per-inch (PPI), and with high frequency. The resultant display device may ensure low cost and performance stability. The conductive layer may be formed by treating the metal oxide semiconductor, which greatly reduces cost in materials and manufacture.

Various embodiments thus include a display panel and a display apparatus. The display panel may include the disclosed array substrates. The display apparatus may include the disclosed display panel. The disclosed display apparatus may be used in a liquid crystal display (LCD) device, organic light-emitting diode (OLED), an electronic paper, a mobile phone, a tablet computer, a television, a monitor, a laptop, a digital photo frame, a navigation system, and/or other products with display function.

The embodiments disclosed herein are exemplary only. Other applications, advantages, alternations, modifications, or equivalents to the disclosed embodiments are obvious to those skilled in the art and are intended to be encompassed within the scope of the present disclosure.

1-21. (canceled)

22. A method for fabricating an array substrate, comprising:
forming a first active layer and common electrodes on a substrate, forming a first gate insulating layer on the first active layer, and forming a gate electrode on the first gate insulating layer;
forming a second gate insulating layer on the common electrodes and the gate electrode, and via-holes in the second gate insulating layer to expose surface portions of the common electrodes;
forming source/drain electrodes electrically connected with the common electrodes through the via-holes; and
forming a second active layer and pixel electrodes on the second gate insulating layer.

23. The method according to claim 22, wherein:
the step of forming a first active layer and common electrodes on the substrate comprises: forming a first oxide layer between the substrate and the first gate insulating layer, and
the first oxide layer has a first portion under the first gate insulating layer used as the first active layer, and has a second portion on the substrate being converted into a conductive layer used as the common electrodes.

24. The method according to claim 23, wherein the second portion of the first oxide layer is converted into the conductive layer by a plasma.

25. The method according to claim 23, wherein the second portion of the first oxide layer is converted into the conductive layer by an ion implantation process.

26. The method according to claim 23, further including:
using a first patterned photoresist layer as an etch mask to form the first active layer, the common electrodes, the first gate insulating layer, and the gate electrode.

27. The method according to claim 26, further including:
forming a first insulating layer on the first oxide layer, and a metal layer on the first insulating layer, and
forming the first patterned photoresist layer on the metal layer used as the etch mask.

28. The method according to claim 27, further including:
forming a through-hole in the metal layer, the first insulating layer, and the first oxide layer to expose the substrate,
removing a first portion of the first patterned photoresist layer containing the through-hole to leave a second portion of the first patterned photoresist layer remain on the metal layer, and
using the second portion of the first patterned photoresist layer as an etch mask to remove portions of the metal layer and the first insulating layer, to provide the gate electrode and the first gate insulating layer.

29. The method according to claim 28, wherein the step of using the second portion of the first patterned photoresist layer as an etch mask to remove portions of the first insulating layer includes a dry etching process using plasma.

30. The method according to claim 29, wherein the dry etching process is controlled to use the plasma to simultaneously treat the first oxide layer to convert the first oxide layer that is not under the first gate insulating layer into the conductive layer.

31. The method according to claim 22, wherein the step of forming a second active layer and pixel electrodes includes:
forming a second oxide layer on the second gate insulating layer and on the source/drain electrodes, and
forming a protection layer on the second oxide layer.

32. The method according to claim 31, further including:
after forming the source/drain electrodes and before forming the second active layer, forming a second patterned photoresist layer on the protection layer, and
using the second patterned photoresist layer on the protection layer as an etch mask to form the second active layer and the pixel electrodes on the second gate insulating layer.

33. An array substrate, comprising:
a first layer comprising a first active layer and common electrodes on a substrate;
a first gate insulating layer on the first active layer;
a gate electrode on the first gate insulating layer;
a second gate insulating layer on the common electrodes and the gate electrode;
source/drain electrodes in the second gate insulating layer and connecting to the common electrodes;
a second active layer on the second gate insulating layer, above the gate electrode, and between the source: drain electrodes; and
pixel electrodes on the second gate insulating layer.

34. The array substrate according to claim 33, wherein:
the first layer is a first oxide layer between the substrate and the first gate insulating layer, and
the first oxide layer has a first portion under the first gate insulating layer defined as the first active layer, and has a second portion being converted into a conductive layer defined as the common electrodes.

35. The array substrate according to claim 34, wherein the second portion of the first oxide layer is converted into the conductive layer by a plasma.

36. The array substrate according to claim 34, wherein the second portion of the first oxide layer is converted into the conductive layer by an ion implantation process.

37. The array substrate according to claim 33, further including:
a second oxide layer on the second gate insulating layer and on the source/drain electrodes,
wherein the second oxide layer has a first portion over the first gate insulating layer defined as the second active layer, and has a second portion being converted into a conductive layer defined as the pixel electrodes.

38. The array substrate according to claim 37, wherein:
the second portion of the second oxide layer is converted into the conductive layer by a plasma or an ion implantation.

39. The array substrate according to claim 33, wherein:
each of the first and second active layers has a thickness ranging from about 30 nm to about 50 nm.

40. The array substrate according to claim 33, wherein:
each of the first and second active layers is made of indium gallium zinc oxide (IGZO), indium zinc oxide (IZO), indium-tin-zinc-oxide (ITZO), zinc oxide (ZnO), or a combination thereof.

41. A display panel, comprising the array substrate of claim 33.
